(19) United States
(12) Patent Application Publication
(10) Pub. No.: US 2006/0109881 A1
(43) Pub. Date: May 25, 2006

(54) Semiconductor laser diode and method of fabricating the same

(75) Inventors: Joon-seop Kwak, Hwaseong-si (KR); Kwang-ki Choi, Suwon-si (KR); Kyoung-ho Ha, Seoul (KR); Yeon-hee Kim, Suwon-si (KR); Jong-in Shim, Gunpo-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electro-Mechanics Co., Ltd., Suwon-si (KR)

(21) Appl. No.: 11/221,872

(22) Filed: Sep. 9, 2005

(30) Foreign Application Priority Data
Nov. 24, 2004 (KR) 10-2004-0097045

(51) Int. Cl. H01S 5/00

(52) U.S. Cl. 372/43.01

(57) ABSTRACT

A semiconductor laser diode and a method of fabricating the same are provided. The semiconductor laser diode includes: a substrate; a predetermined compound semiconductor layer formed on the substrate; a lower cladding layer formed on the compound semiconductor layer; an active layer formed on the lower cladding layer; an upper cladding layer formed on the active layer and having a ridge formed in the middle thereof; trenches formed to a predetermined depth on at least one side of the ridge to penetrate the active layer from the upper cladding layer; a current blocking layer formed on surfaces of the upper cladding layer, except a top surface of the ridge, and inner walls of the trenches; a contact layer formed on the top surface of the ridge; and a first electrode formed on top surfaces of the contact layer and the current blocking layer.

### CROSS-REFERENCE TO RELATED PATENT APPLICATIONS

This application claims the priority of Korean Patent Application No. 10-2004-0097045, filed on Nov. 24, 2004, in the Korean Intellectual Property Office, the disclosure of which is incorporated herein in its entirety by reference.

### BACKGROUND OF THE INVENTION

1. Field of the Invention

The present invention relates to a semiconductor laser diode and a method of fabricating the same, and more particularly, to a ridge-type semiconductor laser diode capable of reducing a leakage current and a method of fabricating the same.

2. Description of the Related Art

In comparison with conventional laser devices semiconductor laser diodes are smaller, and have a smaller threshold current for laser oscillation and higher efficiency. Thus semiconductor laser diodes have been widely used in devices for high speed data transmission or high speed data recording and reading, in particular in devices using optical discs. Especially, nitride based semiconductor laser diodes generate a laser beam with a wavelength from green to an ultraviolet, and are widely applied in high-density optical information storing and reproducing devices, high-resolution laser printers, and projection TVs. An example of such a semiconductor laser diode is a ridge-type semiconductor laser diode.

FIG. 1 is a cross-sectional view of a conventional ridge-type semiconductor laser diode. Referring to FIG. 1, an n-type compound semiconductor layer 12 composed of n-GaN is formed on a sapphire substrate 10. The n-type compound semiconductor layer 12 is divided into two areas R1 and R2 of different heights. A lower cladding layer 14 composed of n-(AlGaN/GaN), a lower waveguide layer composed of n-GaN, an active layer 18 composed of InGaN, an electron blocking layer (EBL) 20 composed of p-AlGaN, an upper waveguide layer 22 composed of p-GaN, and a upper cladding layer 24 composed of p-(AlGaN/GaN) are sequentially laminated in the first area R1 of the n-type compound semiconductor layer 12. A ridge 24a is formed in the middle of the upper cladding layer 24 to limit a current injected from the outside, thereby restricting a resonance area for laser oscillation of the active layer 18. A p-type contact layer 28 is formed on a top surface of the ridge 24a of the uppercladding layer 24, and a current blocking layer 26 composed of SiO₂ is formed on the surfaces of the upper cladding layer 24 except the top surface of the ridge 24a on which the p-type contact layer 28 has been formed. A p-type electrode composed of Au or the like is formed on the p-type contact layer 28 and parts of the upper surface of the current blocking layer 26. Meanwhile, an n-type electrode 40 composed of Ti/Al or the like is formed in the second area R2 of the n-type compound semiconductor layer 12.

In the semiconductor laser diode having the structure as described above, as the respective compound semiconductor layers are grown and formed, more dislocations 50 are present in each of the compound semiconductor layers. Accordingly, when a current injected from the p-type electrode 30 through the p-type contact layer 28 reaches the dislocations 50, the current leaks through the active layer 18.

### SUMMARY OF THE INVENTION

The present invention provides a ridge-type semiconductor laser diode capable of reducing a leakage current and a method of fabricating the same.

According to an aspect of the present invention, there is provided a semiconductor laser diode comprising: a substrate; a predetermined compound semiconductor layer formed on the substrate; a lower cladding layer formed on the compound semiconductor layer; an active layer formed on the lower cladding layer; an upper cladding layer formed on the active layer and having a ridge formed in the middle thereof; trenches formed to a predetermined depth on at least one side of the ridge to penetrate the active layer from the upper cladding layer; a current blocking layerformed on surfaces of the uppercladding layer, except a top surface of the ridge, and inner walls of the trenches; a contact layer formed on the top surface of the ridge; and a first electrode formed on top surfaces of the contact layer and the current blocking layer.

Each of the trenches may be formed in a parallel direction to the ridge.

Each of the trenches may be formed O μm-100 μm or 0.5 μm-20 μm apart from the ridge.

The substrate may be a sapphire substrate or an n-GaN substrate, and the compound semiconductor layer may be composed of n-GaN.

The lower cladding layer and the upper cladding layer may be composed of n-(AlGaN/GaN) and p-(AlGaN/GaN), respectively. Further, the active layer may be a III-V group nitride based compound semiconductor layer of the GaN series composed of InₓAl_{y}Ga_{1-x-y}N (0≦x≦1, 0≦y≦1, and x+y≦1).

A lower waveguide layer may be formed between the lower cladding layer and the active layer, a upper waveguide layer may be formed between the active layer and the upper cladding layer, and the lower waveguide layer and the upper waveguide layer may be composed of n-InₓAl_{y}Ga_{1-x-y}N and p-InₓAl_{y}Ga_{1-x-y}N (0≦x≦1, 0≦y≦1, and x+y≦1), respectively.

An electron blocking layer (EBL) may be formed between the active layer and the upper waveguide layer, and may be composed of p-InₓAl_{y}Ga_{1-x-y}N, InₓAl_{y}Ga_{1-x-y}N (0≦x≦1, 0≦y≦1, and x+y≦1), or InₓAl_{y}Ga_{1-x-y}N/p-InₓAlyGa_{1-x-y}N, multi-quantum layer (0≦x≦1, 0≦y≦1, and x+y≦1).

The EBL may be composed of oxide of at least one element selected from a group consisting of In, Sn, Zn, Ga, Cd, Mg, Be, Ag, Mo, V, Cu, Ir, Rh, Ru, W, Co, Ni, Mn, and La, oxide of at least one element selected from a group consisting of Si, Al, Zr, Ti, and Hf, or nitride of at least one element selected from the group consisting of Si, Al, Zr, Ti, and Mo.

One side of the compound semiconductor layer may be exposed to the outside and a second electrode may be formed on a top surface of the exposed compound semiconductor layer. Alternatively, the second electrode may be formed on a bottom surface of the substrate.

According to another aspect of the present invention, there is provided a method of fabricating a semiconductor laser diode, the method comprising: laminating sequentially a lower cladding layer, an active layer, and an upper cladding layer and depositing a passivation layer on the laminated layers; forming a first photoresist on a top surface of the passivation layer such that a middle portion of the passivation layer is exposed; etching the passivation layer using the first photoresist as an etch mask; forming a contact layer on a top surface of the upper cladding layer that is exposed by etching the passivation layer; forming a second photoresist of a predetermined width on a top surface of the contact layer; forming a ridge in the middle portion of the upper cladding layer by etching the contact layer, upper cladding layer and passivation layer using the second photoresist as an etch mask, and forming trenches penetrating the active layer from the upper cladding layer at both sides of the ridge; forming a current blocking layer on surfaces of the upper cladding layer, except the top surface of the ridge on which the contact layer is formed, and inner walls of the trenches; and forming an electrode on top surfaces of the contact layer and the current blocking layer.

The passivation layer may be composed of SiO₂, and may be etched by a buffered oxide etchant (BOE).

The contact layer, the upper cladding layer, and the passivation layer may be etched using a dry etching method.

### BRIEF DESCRIPTION OF THE DRAWINGS

The above and other features and advantages will become more apparent by describing in detail exemplary embodiments with reference to the attached drawings in which:

FIG. 1 is a cross-sectional view of a conventional ridge-type semiconductor laser diode;

FIG. 2 is a sectional-view of a semiconductor laser diode according to an embodiment of the present invention;

FIGS. 3A and 3B show the measured current-voltage characteristics of the conventional semiconductor laser diode of FIG. 1 and the semiconductor laser diode of FIG. 2 according to an embodiment of the present invention, respectively;

FIGS. 4A through 4G are cross-sectional views for showing a method of fabricating a semiconductor laser diode according to an embodiment of the present invention;

FIGS. 5 and 6 are respectively an optical microscope picture and a scanning electron microscope (SEM) picture showing trenches formed on both sides of a ridge; and

FIG. 7 is a SEM picture showing an enlarged part A of FIG. 6.

### DESCRIPTION OF PREFERRED EMBODIMENTS

Some aspects of the present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will fully convey the concept of the invention to those skilled in the art. In the drawings, the thicknesses of layers and regions are exaggerated for clarity.

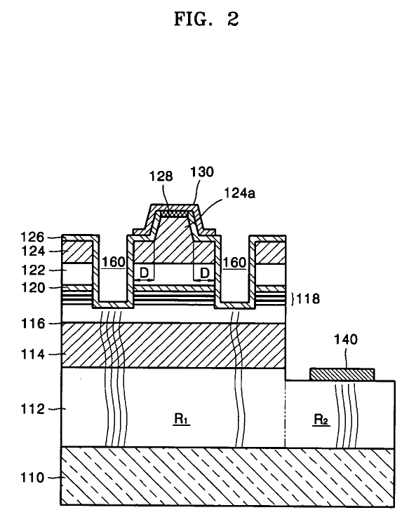

FIG. 2 is a sectional-view of a semiconductor laser diode according to an embodiment of the present invention.

Referring to FIG. 2, a predetermined compound semiconductor layer 112 is formed on a substrate 110. The substrate 110 is generally a sapphire substrate or an n-GaN substrate. The compound semiconductor layer 112 may be composed of n-GaN. The compound semiconductor layer 112 is divided into two areas R1 and R2 of different heights. A lower cladding layer 114, a lower waveguide layer 116, an active layer 118, an upper waveguide layer 122, and an upper cladding layer 124 are sequentially laminated on the first area R1 of the compound semiconductor layer 112. The lower cladding layer 114 and the upper cladding layer 124 may be formed of n-(AlGaN/GaN) and p-(AlGaN/GaN), respectively. The lower waveguide layer 116 and upper waveguide layer 122 that guide laser oscillation and have refractive indexes greater than those of the lower cladding layer 114 and the upper cladding layer 124 can be composed of n-InₓAl_{y}Ga_{1-x-y}N and p-InₓAl_{y}Ga_{1-x-y}N (0≦x≦1, 0≦y≦1, and x+y≦1), respectively. Further, the active layer 118 for laser oscillation has a refraction index higher than those of the lower waveguide layer 114 and upper waveguide layer 122. The active layer 118 can be a III-V group nitride based compound semiconductor layer of GaN series, which is composed of InₓAl_{y}Ga_{1-x-y}N (0≦x≦1, 0≦y≦1, and x+y≦1). The active layer 118 may have a single quantum well structure or a multi quantum well structure. An electron blocking layer (EBL) 120 can be further formed between the active layer 118 and the upper waveguide layer 122. The electron blocking layer 120 may be composed of p-InₓAl_{y}Ga_{1-x-y}N or InxAlyGa_{1-x-y}N (0≦x≦1, 0≦y≦l, and x+y≦1), or composed of InₓAlyGa_{1-x-y}N/p-InₓAl_{y}Ga_{1-x-y}N multiple quantum layer, (0≦x≦1, 0≦y≦1, and x+y≦1).

A ridge 124a is formed on the middle of the upper cladding layer 124 to limit a current injected from the outside, thereby restricting a resonance area for laser oscillation of the active layer 118. Trenches 160, which are respectively formed at both sides of the ridge 124a, penetrate the active layer 118 from the upper cladding layer 124 to a predetermined depth so as to expose the lower waveguide layer 114. The trenches 160 are formed in a parallel direction to the ridge 124a and block the path through which the current leaks. The trenches 160 may be positioned not to affect an optical mode. To this end, the distance D between each of the trenches 160 and the ridge 124a is approximately 0 μm˜100 μm, preferably, 0.5 μm˜20 μm. Meanwhile, unlike FIG. 2, the trench 160 may be formed at only one side of the ridge 124a.

A p-type contact layer 128 is formed on a top surface of the ridge I 24a of the upper cladding layer 124. The contact layer 128 may be composed of Pd. Further, a current blocking layer is formed on the surfaces of the upper cladding layer 124, except the top surface of the ridge I 24a, and the inner wall surfaces of the trenches 160. The current blocking layer 126 may be composed of oxide of at least one element selected from the group consisting of In, Sn, Zn, Ga, Cd, Mg, Be, Ag, Mo, V, Cu, Ir, Rh, Ru, W, Co, Ni, Mn, and La, oxide of at least one element selected from the group consisting of Si, Al, Zr, Ti, and Hf, or nitride of at least one element selected from the group consisting of Si, Al, Zr, Ti, and Mo.

A first electrode 130 is formed on a top surface of the contact layer 128 and a top surface of the current blocking layer 126. T he first electrode 130 is a p-type electrode, and may be composed of, for example, Au. Meanwhile, a second electrode 140 is formed on a top surface of the second area R2 of the compound semiconductor layer 112. The second electrode 140 is an n-type electrode, and may be composed of, for example, Ti/Al.

Alternatively, the second electrode 140 can also be formed on a bottom surface of the substrate 110.

As described above, since the trenches 160 are formed on at least one side of the ridge 124a of the upper cladding layer 124 to penetrate the active layer 118 from the upper cladding layer 124, the path through which the current leaks can be blocked, and accordingly, a current leakage through defects such as dislocations present inside of each of semiconductor layers can be prevented.

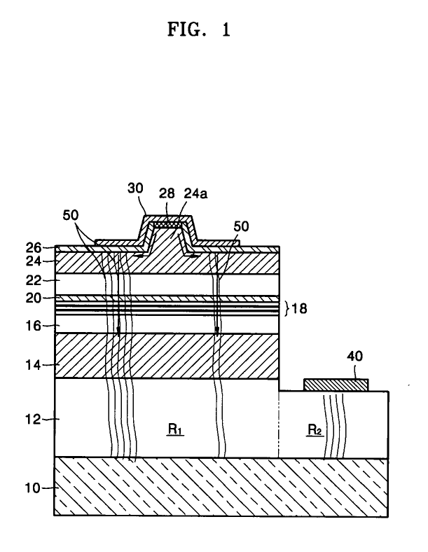

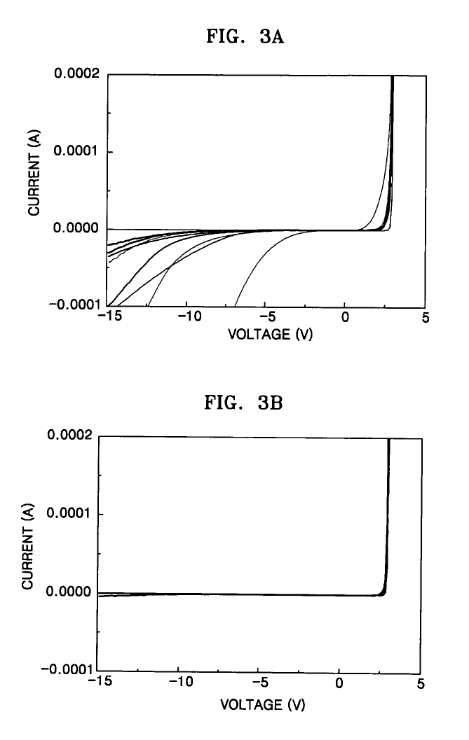

FIGS. 3A and 3B show the measured current-voltage characteristic of the conventional semiconductor laser diode of FIG. 1 and the semiconductor laser diode of FIG. 2 according to an embodiment of the present invention, respectively. Referring to FIGS. 3A and 3B, a current leakage is rarely generated in the semiconductor laser diode according to the present invention when compared to the conventional semiconductor laser diode.

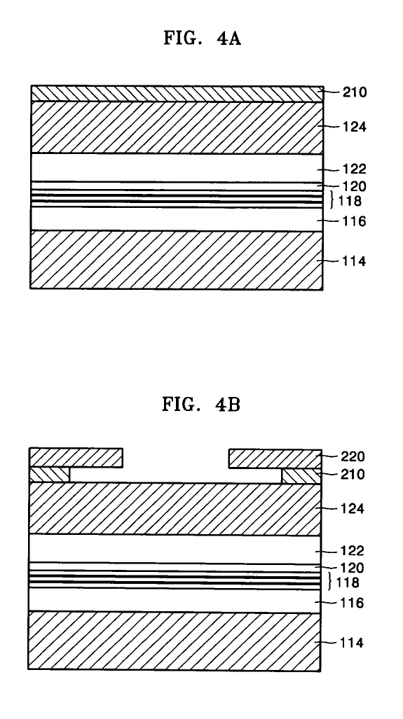

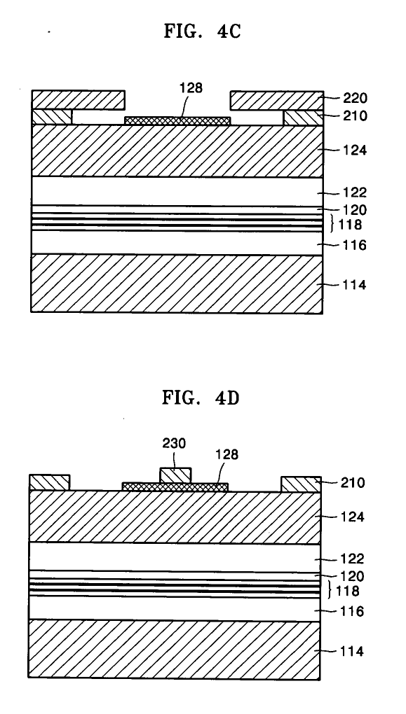

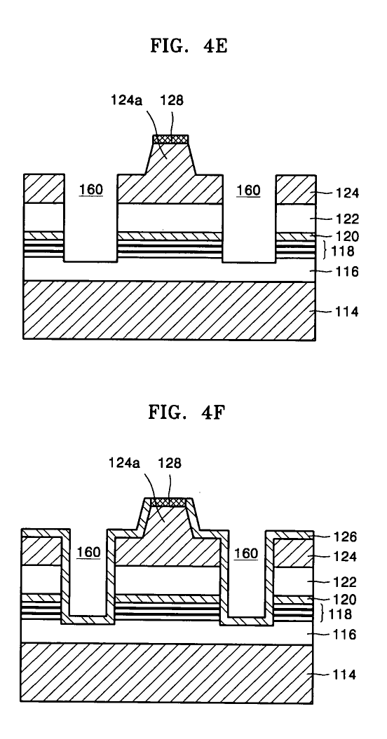

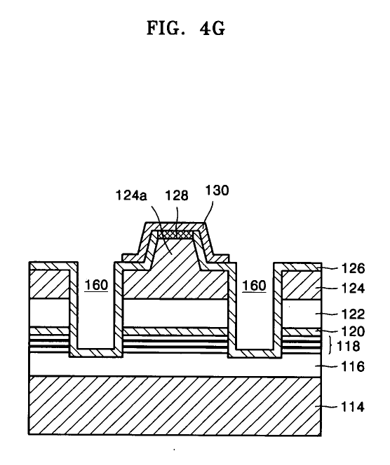

FIGS. 4A through 4G are cross-sectional views for showing a method of fabricating a semiconductor laser diode according to an embodiment of the present invention. Referring to FIG. 4A, a predetermined compound semiconductor layer (not shown) is formed on a substrate (not shown), and subsequently, a lower cladding layer 114, a lower waveguide layer 116, an active layer 118, a upper waveguide layer 122, and an upper cladding layer 124 are subsequently laminated on the predetermined compound semiconductor layer. The substrate may be a sapphire substrate or an n-GaN substrate, and the compound semiconductor layer may be composed of n-GaN. Further, the lower cladding layer 114 and the upper cladding layer 124 may be composed of n-(AlGaN/GaN) and p-(AlGaN/GaN), respectively. The lower waveguide layer 116 and the upper waveguide layer 122 may be composed of n-InₓAl_{y}Ga_{1-x-y}N and p-InₓAl_{y}Ga_{1-x-y}N (0≦x≦1, 0≦y≦1, and x+y≦1), respectively. The active layer 118 may be a III-V group nitride based compound semiconductor layer of the GaN series which is composed of InₓAl_{y}Ga_{1-x-y}N (0≦x≦1, 0≦y≦1, and x+y≦1). An EBL 120 may be further formed between the active layer 118 and the upper waveguide layer 122. The EBL 120 may be composed of p-InₓAl_{y}Ga_{1-x-y}N, InₓAl_{y}Ga_{1-x-y}N (0≦x≦1, 0≦y≦1, and x+y≦1), or InₓAl_{y}Ga_{1-x-y}N/p-InₓAl_{y}Ga_{1-x-y}N multi-quantum layer (0≦x≦1, 0≦y≦1, and x+y≦1). A passivation layer 210 is deposited on a top surface of the upper cladding layer 124. The passivation layer 210 may be composed of SiO₂.

Referring to FIG. 4B, a first photoresist is coated on a top surface of the passivation layer 210 and patterned to expose the middle of the passivation layer 210. The patterned first photoresist 220 is used as an etch mask and the passivation layer 210 is etched. At this moment, the passivation layer 210 is over etched such that the etched width of the passivation layer 210 is larger than the width exposed through the patterned first photoresist 220. The etching process of the passivation layer 210 can be performed by removing SiO₂ using a buffered oxide etchant (BOE).

Referring to FIG. 4C, subsequently, a p-type contact layer 128 is formed on the top surface of the upper cladding layer 124 that is exposed by etching the passivation layer 210. The p-type contact layer 128 may be composed of Pd.

Referring to FIG. 4D, after the first photoresist 220 is removed, a second photoresist is coated and then is patterned. Accordingly, the patterned second photoresist 230 of a predetermined width is formed on a top surface of the p-type contact layer 128. The patterned second photoresist 230 may be formed with a width of about 2 μm.

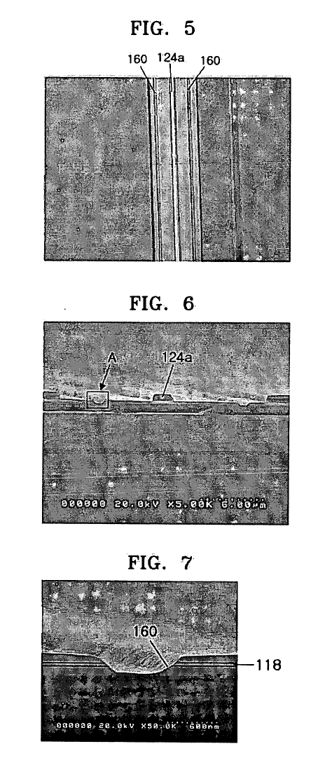

Next, when the patterned second photoresist 230 is used as an etch mask, the p-type contact layer 128, the upper cladding layer 124, and the passivation layer 210 are etched for a predetermined period of time using the patterned second photoresist 230, a ridge I 24a of a predetermined width is formed in the middle of the upper cladding layer 124, and trenches 160, which penetrate the active layer 118 from the upper cladding layer 124 to expose the lower waveguide layer 116, are formed at both sides of the ridge 124a in a parallel direction to the ridge 124a, respectively. The etching process of the p-type contact layer 128, upper cladding layer 124 and passivation layer 210 can be performed using a dry etching method. Each of the trenches 160 may be formed so as to be located at a distance of about O μm˜100 μm, preferably about 0.5 μm˜20 μm, from the ridge 124a in order not to affect an optical mode. The p-type contact layer 128 is formed by etching on a top surface of the ridge 124a of the upper cladding layer 124. FIGS. 5 and 6 are, respectively, an optical microscope picture and a scanning electron microscope (SEM) picture-showing trenches formed on both sides of the ridge 124a. Further, FIG. 7 is a SEM picture showing an enlarged part A of FIG. 6. Referring FIG. 7, the trenches 160 are formed by penetrating the active layer 118.

Referring to FIG. 4F, a current blocking layer 126 is formed on the surfaces of the upper-cladding layer 124, except the top surface of the ridge 124a on which the p-type contact layer 128 is formed, and inner wall surfaces of the trenches 160. The current blocking layer 126 may be composed of oxide of at least one element selected from the group consisting of In, Sn, Zn, Ga, Cd, Mg, Be, Ag, Mo, V, Cu, Ir, Rh, Ru, W, Co, Ni, Mn, and La, oxide of at least one element selected from the group consisting of Si, Al, Zr, Ti, and Hf, or nitride of at least one element selected from the group consisting of Si, Al, Zr, Ti, and Mo.

Referring to FIG. 4G, a first electrode 130 that is a p-type electrode is formed on the top surface of the p-type contract layer 128 and on a top surface of the current blocking layer 126 disposed at both sides of the p-type contact layer 128. The first electrode 130 can be formed by laminating a metal material such as Au to cover the p-type contact layer 128 and the current blocking layer 126, and subsequently patterning the metal material.

While not illustrated in FIGS. 4A through 4G, a second electrode (reference numeral 140 of FIG. 2) that is an n-type electrode may be formed on a top surface of the compound semiconductor layer 112 or a bottom surface of the substrate 110, as described above. Also, various changes in the order of forming the second electrode 140 can be made.

As described above, trenches which penetrate an active layer from an upper cladding layer are formed at both sides of a ridge of the upper cladding layer, and, thereby a path through which current leaks can be blocked. Accordingly, a current leakage through defects such as dislocations present in each of the semiconductor layers constructing a semiconductor laser diode can be prevented.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor laser diode comprising:
a substrate;
a predetermined compound semiconductor layer formed on the substrate;
a lower cladding layer formed on the compound semiconductor layer;
an active layer formed on the lower cladding layer;
an upper cladding layer formed on the active layer and having a ridge formed in the middle thereof;
trenches formed to a predetermined depth on at least one side of the ridge to penetrate the active layer from the upper cladding layer;
a current blocking layer formed on surfaces of the upper cladding layer, except a top surface of the ridge, and inner walls of the trenches;
a contact layer formed on the top surface of the ridge; and
a first electrode formed on top surfaces of the contact layer and the current blocking layer.

2. The semiconductor laser diode of claim 1, wherein each of the trenches is formed in a parallel direction to the ridge.

3. The semiconductor laser diode of claim 2, wherein each of the trenches is formed 0 μm˜100 μm apart from the ridge.

4. The semiconductor laser diode of claim 3, wherein each of the trenches is formed 0.5 μm-20 μm apart from the ridge.

5. The semiconductor laser diode of claim 1, wherein the substrate is a sapphire substrate or an n-GaN substrate.

6. The semiconductor laser diode of claim 1, wherein the compound semiconductor layer is composed of n-GaN.

7. The semiconductor laser diode of claim 1, wherein the lower cladding layer and the upper cladding layer are composed of n-(AlGaN/GaN) and p-(AlGaN/GaN), respectively.

8. The semiconductor laser diode of claim 1, wherein the active layer is a III-V group nitride based compound semiconductor layer of the GaN series composed of InₓAl_{y}Ga_{1-x-y}N (0≦x≦1, 0≦y≦1, and x+y≦1).

9. The semiconductor laser diode of claim 1, wherein a lower waveguide layer is formed between the lower cladding layer and the active layer and a upper waveguide layer is formed between the active layer and the upper cladding layer.

10. The semiconductor laser diode of claim 9, wherein the lower waveguide layer and the upper waveguide layer are composed of n-InₓAl_{y}Ga_{1-x-y}N and p-InₓAl_{y}Ga_{1-x-y}N (0≦x≦1, 0≦y≦1, and x+y≦1), respectively.

11. The semiconductor laser diode of claim 9, wherein an electron blocking layer (EBL) is formed between the active layer and the upper waveguide layer.

12. The semiconductor laser diode of claim 11, wherein the EBL is composed of p-InₓAl_{y}Ga_{1-x-y}N, InₓAl_{y}Ga_{1-x-y}N (0≦x≦1, 0≦y≦1, and x+y≦1), or InₓAl_{y}Ga_{1-x-y}N/p-InₓAl_{y}Ga_{1-x-y}N multi-quantum layer (0≦x≦1, 0≦y≦1, and x+y≦1).

13. The semiconductor laser diode of claim 1, wherein the EBL is composed of oxide of at least one element selected from a group consisting of In, Sn, Zn, Ga, Cd, Mg, Be, Ag, Mo, V, Cu, Ir, Rh, Ru, W, Co, Ni, Mn, and La.

14. The semiconductor laser diode of claim 1, wherein the EBL is composed of oxide of at least one element selected from a group consisting of Si, Al, Zr, Ti, and Hf.

15. The semiconductor laser diode of claim 1, wherein the EBL is composed of nitride of at least one element selected from a group consisting of Si, Al, Zr, Ti, and Mo.

16. The semiconductor laser diode of claim 1, wherein one side of the compound semiconductor layer is exposed to the outside and a second electrode is formed on a top surface of the exposed compound semiconductor layer.

17. The semiconductor laser diode of claim 1, wherein a second electrode is formed on a bottom surface of the substrate.

18. A method of fabricating a semiconductor laser diode, the method comprising:
laminating sequentially a lower cladding layer, an active layer, and an upper cladding layer and depositing a passivation layer on the laminated layers;
forming a first photoresist on a top surface of the passivation layer such that a middle portion of the passivation layer is exposed;
etching the passivation layer using the first photoresist as an etch mask;
forming a contact layer on a top surface of the upper cladding layer that is exposed by etching the passivation layer;
forming a second photoresist of a predetermined width on a top surface of the contact layer;
forming a ridge in the middle portion of the upper cladding layer by etching the contact layer, upper cladding layer and passivation layer using the second photo resist as an etch mask, and forming trenches penetrating the active layer from the upper cladding layer at both sides of the ridge;
forming a current blocking layer on surfaces of the upper cladding layer, except the top surface of the ridge on which the contact layer is formed, and inner walls of the trenches; and
forming an electrode on top surfaces of the contact layer and the current blocking layer.

19. The method of claim 18, wherein each of the trenches is formed in a parallel direction to the ridge.

20. The method of claim 19, wherein each of the trenches is formed 0 μm˜100 μm apart from the ridge.

21. The method of claim 20, wherein each of the trenches is formed 0.5 μm˜20 μm apart from the ridge.

22. The method of claim 18, wherein a lower waveguide layer is formed between the lower cladding layer and the active layer and a upper waveguide layer is formed between the active layer and the upper cladding layer.

23. The method of claim 22, wherein an electron blocking layer (EBL) is formed between the active layer and the upper waveguide layer.

24. The method of claim 18, wherein the passivation layer is composed of SiO₂.

25. The method of claim 18, wherein the passivation layer is etched such that the etched width is larger than a width exposed through the first photoresist.

26. The method of claim 25, wherein the passivation layer is etched by a buffered oxide etchant (BOE).

27. The method of claim 18, wherein the contact layer, the upper cladding layer, and the passivation layer are etched using a dry etching method.

28. The method of claim 18, wherein the current blocking layer is composed of oxide of at least one element selected from a group consisting of In, Sn, Zn, Ca, Cd, Mg, Be, Ag, Mo, V, Cu, Ir, Rh, Ru, W, 00, Ni, Mn, and La.

29. The method of claim 18, wherein the current blocking layer is composed of oxide of at least one element selected from a group consisting of Si, Al, Zr, Ti, and Hf.

30. The method of claim 18, wherein the current blocking layer is composed of nitride of at least one element selected from a group consisting of Si, Al, Zr, Ti, and Mo.
